(19) United States
(12) Patent Application Publication
(10) Pub. No.: US 2023/0342624 A1
(43) Pub. Date: Oct. 26, 2023

(54) BIOCHEMICAL COMPUTER LATCH BASED ON ENZYMATIC REACTIONS

(71) Applicant: SOUTH CHINA UNIVERSITY OF TECHNOLOGY, Guangzhou (CN)

(72) Inventors: Han HUANG, Guangzhou (CN); Chengzhi MA, Guangzhou (CN); Xinglong XIAO, Guangzhou (CN); Tongli HE, Guangzhou (CN)

(73) Assignee: SOUTH CHINA UNIVERSITY OF TECHNOLOGY, Guangzhou (CN)

(21) Appl. No.: 18/342,747

(22) Filed: Jun. 28, 2023

Related U.S. Application Data
(63) Continuation of application No. PCT/CN2021/090795, filed on Apr. 29, 2021.

(30) Foreign Application Priority Data
Mar. 15, 2021 (CN) 202110278299.7

(51) Int. Cl. G06N 3/123

(52) U.S. Cl. CPC G06N 3/123

(57) ABSTRACT

Disclosed is a biochemical computer latch based on enzymatic reactions. Input, output and storage signals of the latch are concentrations or activities of substances or enzymes. Bistable characteristics of the latch are implemented by a plurality of enzymatic reactions that interact with each other. When the plurality of enzymatic reactions are catalyzed by each other, a positive feedback regulation of enzyme concentration or activity can be achieved, so that the biochemical computer latch can be stabilized in one of a plurality of states and stores information in the state. The latch can change the state thereof by means of a change in the input signal, so as to modify the stored information, and can also read the stored information by means of the output signal. Compared with traditional semiconductor latches, the disclosed can be more conveniently used in biochemical computers without conversion between an electrical signal and a chemical signal.

### CROSS-REFERENCE TO RELATED APPLICATION

This application is a continuation of international application of PCT application serial no. PCT/CN2021/090795 filed on Apr. 29, 2021, which claims the priority benefit of China application no. 202110278299.7 filed on Mar. 15, 2021. The entirety of each of the mentioned above patent applications is hereby incorporated by reference herein and made a part of this specification.

### TECHNICAL FIELD

The present invention relates to the technical field of biochemical computers, in particular to a biochemical computer latch based on enzymatic reactions.

### BACKGROUND

Building a biochemical computer with low power consumption and high performance by imitating the brain of a living being is currently a very promising subject, and a storage unit is an essential component of the biochemical computer. At present, storage components based on biochemistry mainly include a DNA-based storage which is based on the DNA transcription and translation process, so that the response speed is low, and it often takes several hours to read information from and write information into the storage, which may decrease the computing speed of the biochemical computer and fail to meet the requirements of high-performance biochemical computers. Therefore, it is urgent to find a more efficient way of biochemical storage.

### SUMMARY

The present invention aims to solve the defects of low speed and large delay of reading and writing of a DNA-based biochemical reaction memory in the prior art, and provides a biochemical computer latch based on enzymatic reactions. The concentrations or activities of substances or enzymes are used as input, output and storage signals, and the concentration and activity of other substances and enzymes are driven to change through a change in enzyme activity, such that the bistable characteristics and write and read functions of the latch are achieved.

The objective of the present invention may be implemented through the following technical solutions:

A biochemical computer latch based on enzymatic reactions includes an input signal, an output signal, and a storage signal, wherein the input signal and the output signal are concentrations or activities of substances, the storage signal is a concentration or activity of enzymes, and the storage signal includes an information storage enzyme and an inverse information storage enzyme.

In one aspect, the concentration or activity of the information storage enzyme is influenced by the inverse information storage enzyme: in the case that the concentration or activity of the inverse information storage enzyme is high, generation of the information storage enzyme is inhibited or consumption of the information storage enzyme is promoted, resulting in a decrease of the concentration or activity of the information storage enzyme; and in the case that the concentration or activity of the inverse information storage enzyme is low, the generation of the information storage enzyme is promoted or the consumption of the information storage enzyme is inhibited, resulting in an increase of the concentration or activity of the information storage enzyme.

In another aspect, the concentration or activity of the inverse information storage enzyme is also influenced by the information storage enzyme: in the case that the concentration or activity of the information storage enzyme is high, generation of the inverse information storage enzyme is inhibited or consumption of the inverse information storage enzyme is promoted, resulting in a decrease of the concentration or activity of the inverse information storage enzyme; and in the case that the concentration or activity of the information storage enzyme is low, the generation of the inverse information storage enzyme is promoted or the consumption of the inverse information storage enzyme is inhibited, resulting in an increase of the concentration or activity of the inverse information storage enzyme.

Due to the above-mentioned interplay between the concentration or activity of the information storage enzyme and the concentration or activity of the inverse information storage enzyme, a positive feedback regulation is achieved through changes in the concentration or activity of the information storage enzyme and the concentration or activity of the inverse information storage enzyme, such that the biochemical computer latch achieves bistable characteristics and is used to store one bit of information: in the case that the concentration of the information storage enzyme is high, the concentration of the inverse information storage enzyme decreases accordingly, and then the concentration of the information storage enzyme increase due to that the concentration of the inverse information storage enzyme becomes low, so as to achieve a positive feedback change that the concentration or activity of the information storage enzyme continuously increases and the concentration or activity of the inverse information storage enzyme continuously decreases, until the concentration or activity of the information storage enzyme reaches an upper limit and is stable and the concentration or activity of the inverse information storage enzyme reaches a lower limit and is stable, in this case, the biochemical computer latch reaches a stable state upon the positive feedback regulation, the concentration or activity of the information storage enzyme is high, the concentration or activity of the inverse information storage enzyme is low, and at this time a storage state of the biochemical computer latch is logic 1; and in the case that the concentration of the information storage enzyme is low, the concentration or activity of the inverse information storage enzyme increases accordingly, and then the concentration or activity of the information storage enzyme decreases due to that the concentration or activity of the inverse information storage enzyme becomes high, so as to achieve a positive feedback change that the concentration or activity of the information storage enzyme continuously decreases and the concentration or activity of the inverse information storage enzyme continuously increases, until the concentration or activity of the information storage enzyme reaches a lower limit and is stable and the concentration or activity of the inverse information storage enzyme reaches an upper limit and is stable, in this case, the biochemical computer latch reaches a stable state upon the positive feedback regulation, the concentration or activity of the information storage enzyme is low, the concentration or activity of the inverse information storage enzyme is high, and at this time the storage state of the biochemical computer latch is logic 0.

Preferably, the concentration or activity of the information storage enzyme and the concentration or activity of the inverse information storage enzyme are influenced by the concentration or activity of an input signal substance. Therefore, the concentration or activity of the information storage enzyme and the concentration or activity of the inverse information storage enzyme may be changed by a change in the concentration or activity of the input signal substance, such that the storage state of the biochemical computer latch is changed, and writing of data into the biochemical computer latch is achieved.

Preferably, the concentration or activity of the output signal substance is influenced by the concentration or activity of the information storage enzyme and the concentration or activity of the inverse information storage enzyme. Therefore, whether the concentration or activity of the information storage enzyme and the concentration or activity of the inverse information storage enzyme are high or low may be output by the concentration or activity of the output signal substance. Since enzymes, as a catalyst of a reaction, are not consumed after the reaction, the output substance does not destroy the original storage state of the biochemical computer latch while reading the state of the biochemical computer latch.

Preferably, the input signal of the biochemical computer latch includes a data writing enzyme and a writing control enzyme, data is written into the information storage enzyme by the data writing enzyme so as to be held in the latch, and the writing control enzyme controls whether to enable writing of the data writing enzyme.

Preferably, the biochemical computer latch is set as logic 1 via a set enzyme, and the biochemical computer latch is set as logic 0 via a reset enzyme.

### BRIEF DESCRIPTION OF DRAWINGS

FIG. 1 is a schematic diagram of a biochemical computer latch according to an embodiment of the present invention.

FIG. 2 is a schematic diagram of a biochemical reaction computer D latch according to an embodiment of the present invention.

### DETAILED DESCRIPTION OF EMBODIMENTS

In order to make the objective, technical solutions and advantages of embodiments of the present invention clearer, the technical solutions in the embodiments of the present invention will be clearly and completely described below with reference to the accompanying drawings according to the embodiments of the present invention. Apparently, the embodiments described hereinafter are a part of the embodiments of the present invention, rather than all the embodiments. Based on the embodiments of the present invention, all other embodiments obtained by a person of ordinary skill in the art without creative efforts fall within the scope of the present invention.

### Embodiment 1

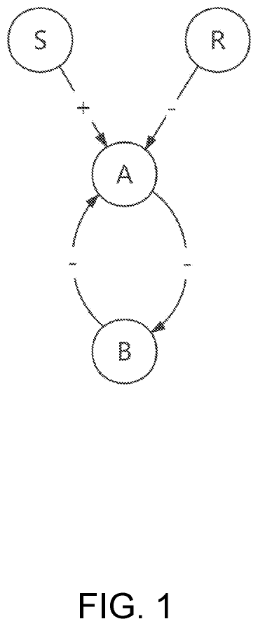

As shown in FIG. 1, a biochemical computer latch according to this embodiment includes an information storage enzyme A, an inverse information storage enzyme B, an input signal substance S, and an input signal substance R.

The biochemical computer latch may be set as 1 via the input signal substance S, and the biochemical computer latch may be set as 0 via the input signal substance R. The information storage enzyme A may catalyze the consumption of the inverse information storage enzyme B to decrease the concentration of the inverse information storage enzyme B. The information storage enzyme A may be spontaneously generated at a rate to increase the concentration of A. The inverse information storage enzyme B may catalyze the consumption of the information storage enzyme A to decrease the concentration of the information storage enzyme A. The inverse information storage enzyme B may be spontaneously generated at a rate to increase the concentration of the inverse information storage enzyme B. The input signal substance S may catalyze the generation of the information storage enzyme A to increase the concentration of the information storage enzyme A. The input signal substance R may catalyze the consumption of the information storage enzyme A to decrease the concentration of the information storage enzyme A.

In the case that the concentrations of the input signal substance S and the input signal substance R are low, the biochemical computer latch has the function of stably holding data. In the case that the biochemical computer latch stores logic 0, the concentration of the information storage enzyme A is low, and the concentration of the inverse information storage enzyme B is high; as the concentration of the inverse information storage enzyme B is high, the consumption of A is promoted, which causes that the concentration of A is always kept low; as the concentration of the information storage enzyme A is low, the consumption rate of the inverse information storage enzyme B is low, and the generation rate of the inverse information storage enzyme B is not influenced, such that the concentration of the inverse information storage enzyme B is kept high; in this way, the biochemical computer latch maintains a stable state and stores logic 0. In the case that the biochemical computer latch stores logic 1, the concentration of A is high and the concentration of B is low; as the consumption rate of the information storage enzyme A is low when the concentration of B is low, and the generation rate of the information storage enzyme A is not influenced, the concentration of the information storage enzyme A is kept high; as the concentration of the information storage enzyme A is high, the consumption of the inverse information storag e enzyme B is promoted, which causes that the concentration of the inverse information storage enzyme B is always kept low; in this way, the biochemical computer latch maintains a stable state and stores logic 1.

In the case that the concentrations of the input signal substance S and the input signal substance R are high, the biochemical computer latch may write data according to an input signal and hold the data. In the case that the concentration of the input signal substance S is high, the generation of the information storage enzyme A is promoted, the generation rate of the information storage enzyme A increases, the concentration of the information storage enzyme A increases to a high concentration, then the concentration of the inverse information storage enzyme B decreases, and a positive feedback regulation is performed until reaching a stable state that the information storage enzyme A is in a high concentration and the inverse information storage enzyme B is in a low concentration, such that the storage state of the biochemical computer latch changes to logic 1, achieving the operation of writing logic 1 into the latch. In the case that the concentration of the input signal substance R is high, the consumption of the information storage enzyme A is promoted, the consumption rate of the information storage enzyme A increases, the concentration of the information storage enzyme A decreases to a low concentration, then the concentration of the inverse information storage enzyme B increases, and the positive feedback regulation is performed until reaching a stable state that the information storage enzyme A is in a low concentration and the inverse information storage enzyme B is in a high concentration, such that the storage state of the biochemical computer latch changes to logic 0, achieving the operation of writing logic 0 into the latch.

### Embodiment 2

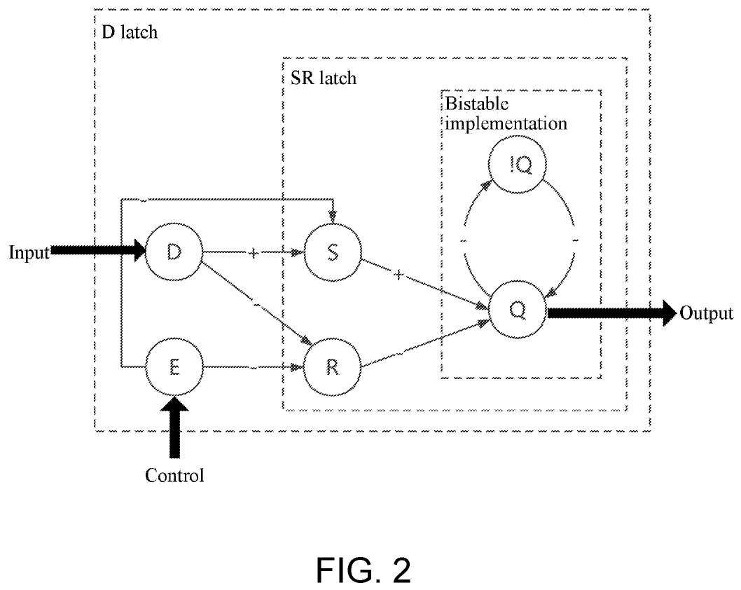

As shown in FIG. 2, a biochemical reaction computer D latch according to this embodiment includes an information storage enzyme Q, an inverse information storage enzyme !Q, a set enzyme S, a reset enzyme R, a data writing enzyme D, and a writing control enzyme E.

The biochemical computer latch may be set as logic 1 via the set enzyme S, and the biochemical computer latch may be set as logic 0 via the reset enzyme R. Data may be written to the information storage enzyme Q by the data writing enzyme D so as to be held in the latch, and the writing control enzyme E may control whether to enable writing of the data writing enzyme D.

The information storage enzyme Q may catalyze the consumption of the inverse information storage enzyme !Q to decrease the concentration of the inverse information storage enzyme !Q. The information storage enzyme Q may be spontaneously generated at a rate to increase the concentration of Q. The inverse information storage enzyme !Q may catalyze the consumption of the information storage enzyme Q to decrease the concentration of the information storage enzyme Q. The inverse information storage enzyme !Q may be spontaneously generated at a rate to increase the concentration of the inverse information storage enzyme !Q. The input signal substance S may catalyze the generation of the information storage enzyme Q to increase the concentration of the information storage enzyme Q. The input signal substance R may catalyze the consumption of the information storage enzyme Q to decrease the concentration of the information storage enzyme Q. The data writing enzyme D may promote the generation of the set enzyme S and promote the decomposition of the reset enzyme R. The writing control enzyme E may promote the decomposition of the set enzyme S and the reset enzyme R at the same time.

In the case that the concentration of the writing control enzyme E is high, S and R are inhibited so that the concentrations of S and R decrease to be low, the concentrations of the information storage enzyme Q and the inverse information storage enzyme !Q are kept unchanged, and the latch is in a non-writable state and holds the current data stably. In the case that the concentration of the writing control enzyme E is low, the inhibition of the set enzyme S and the reset enzyme R by the writing control enzyme E disappears, and the concentrations of the set enzyme S and the reset enzyme R are influenced by the data writing enzyme D. In the case that the concentration of the data writing enzyme D is low, the concentration of the set enzyme S is low, the reset enzyme R is no longer inhibited by the data writing enzyme D and the writing control enzyme E so that the concentration of the reset enzyme R increases, accordingly, the concentration of the information storage enzyme Q decreases, the data stored in the latch becomes logic 0, and information of the data writing enzyme D is successfully written into the latch to obtain logic 0. In the case that the concentration of the data writing enzyme D is high, the reset enzyme R is inhibited by the data writing enzyme D so that the concentration of the reset enzyme R decreases to a low concentration, the set enzyme S is promoted by the data writing enzyme D so that the concentration of the set enzyme S increases to a high concentration, accordingly, the concentration of the information storage enzyme Q becomes a high concentration, the data stored in the latch becomes logic 1, and the information of the data writing enzyme D is successfully written into the latch to obtain logic 1.

Compared with the prior art, the present invention has the following advantages and beneficial effects:

(1) Since the input, output and storage signals of the biochemical computer latch are the concentrations or activities of substances or enzymes, the biochemical computer latch according to the present invention can be conveniently cascaded with biochemical reaction logic gates to constitute sequential logic, and can be used in a biochemical computer without conversion between an electrical signal and a chemical signal.

(2) The biochemical computer latch according to the present invention has a higher read/write speed and smaller delay due to the high reaction speed of the enzymatic reactions on which the biochemical computer latch is based, and can achieve a low delay at the level of milliseconds to picoseconds.

(3) The biochemical computer latch according to the present invention does not need to rely on DNA transcription and translation, such that the biochemical computer latch can operate normally without relying on living cells and can be used more flexibly.

The above embodiments are preferred implementations of the present invention, but the implementations of the present invention are not limited thereto. Any other changes, modifications, substitutions, combinations and simplifications made without departing from the spirit and principles of the present invention are to be construed as equivalent substitutions within the scope of the present invention.

What is claimed is:

1. A biochemical computer latch based on enzymatic reactions, wherein the biochemical computer latch based on enzymatic reactions comprises an input signal, an output signal, and a storage signal, wherein the input signal and the output signal are concentrations or activities of substances; the storage signal is a concentration or activity of enzymes; and the storage signal comprises an information storage enzyme and an inverse information storage enzyme.

2. The biochemical computer latch based on enzymatic reactions according to claim 1, wherein the concentration or activity of the information storage enzyme is influenced by the inverse information storage enzyme: in the case that the concentration or activity of the inverse information storage enzyme is high, generation of the information storage enzyme is inhibited or consumption of the information storage enzyme is promoted, resulting in a decrease of the concentration or activity of the information storage enzyme; and in the case that the concentration or activity of the inverse information storage enzyme is low, the generation of the information storage enzyme is promoted or the consumption of the information storage enzyme is inhibited, resulting in an increase of the concentration or activity of the information storage enzyme.

3. The biochemical computer latch based on enzymatic reactions according to claim 1, wherein the concentration or activity of the inverse information storage enzyme is influenced by the information storage enzyme: in the case that the concentration or activity of the information storage enzyme is high, generation of the inverse information storage enzyme is inhibited or consumption of the inverse information storage enzyme is promoted, resulting in a decrease of the concentration or activity of the inverse information storage enzyme; and in the case that the concentration or activity of the information storage enzyme is low, the generation of the inverse information storage enzyme is promoted or the consumption of the inverse information storage enzyme is inhibited, resulting in an increase of the concentration or activity of the inverse information storage enzyme.

4. The biochemical computer latch based on enzymatic reactions according to claim 1, wherein a positive feedback regulation is achieved by changes in the concentration or activity of the information storage enzyme and the concentration or activity of the inverse information storage enzyme, such that the biochemical computer latch achieves bistable characteristics and is used to store one bit of information: in the case that the concentration or activity of the information storage enzyme is high and the concentration or activity of the inverse information storage enzyme is low, a storage state of the biochemical computer latch is logic 1; and in the case that the concentration or activity of the information storage enzyme is low and the concentration or activity of the inverse information storage enzyme is high, the storage state of the biochemical computer latch is logic 0.

5. The biochemical computer latch based on enzymatic reactions according to claim 1, wherein the concentration or activity of the information storage enzyme and the concentration or activity of the inverse information storage enzyme are influenced by the concentration or activity of an input signal substance.

6. The biochemical computer latch based on enzymatic reactions according to claim 1, wherein the concentration or activity of the output signal substance is influenced by the concentration or activity of the information storage enzyme and the concentration or activity of the inverse information storage enzyme.

7. The biochemical computer latch based on enzymatic reactions according to claim 1, wherein the input signal of the biochemical computer latch comprises a data writing enzyme and a writing control enzyme, wherein data is written into the information storage enzyme by the data writing enzyme so as to be held in the latch, and the writing control enzyme controls whether to enable writing of the data writing enzyme.

8. The biochemical computer latch based on enzymatic reactions according to claim 1, wherein the biochemical computer latch is set as logic 1 via a set enzyme, and the biochemical computer latch is set as logic 0 via a reset enzyme.
